(19) United States
(12) Patent Application Publication
(10) Pub. No.: US 2010/0287012 A1
(43) Pub. Date: Nov. 11, 2010

(54) Method and system for measuring carbon dioxide reduction

(75) Inventors: Arne Ballantine, Palo Alto, CA (US); Ian Russell, Sunnyvale, CA (US); Scott Reynolds, San Francisco, CA (US)

Correspondence Address: The Marbury Law Group, PLLC, 11800 SUNRISE VALLEY DRIVE, SUITE 1000, RESTON, VA, 20191, US

(73) Assignee: BLOOM ENERGY CORPORATION

(21) Appl. No.: 12/078,926

(22) Filed: Apr. 8, 2008

(51) Int. Cl. G06Q 10/00; G06F 19/00; G01R 21/00; G06F 17/30; G06Q 30/00

(52) U.S. Cl. 705/7; 702/24; 707/769; 702/62; 707/E17.014

(57) ABSTRACT

A system and method is provided for managing energy data. The system includes a energy transformation device, a central energy data management system and a database containing carbon dioxide credit information. Managing the energy data includes measuring an amount of power produced or consumed by an energy transformation device, measuring an amount of carbon dioxide emitted, converted or sequestered by the energy transformation device, creating a dataset of the power produced or consumed and the amount of carbon dioxide emitted or sequestered, and transmitting the dataset and characteristic data to a central energy data management system. The method also includes, receiving energy measurements and characteristic data from an energy transformation device, obtaining carbon dioxide credit information and comparing the received energy measurements and the characteristic data with the received carbon dioxide credit information to obtain a carbon dioxide credit for the energy transformation device.

### BACKGROUND OF THE INVENTION

The following description of the background of the invention is provided simply as an aid in understanding the invention and is not admitted to describe or constitute prior art to the invention.

The present invention relates generally to the field of managing energy data. Specifically, the present invention is directed to a system and method for reducing carbon dioxide emissions and tracking the reductions through the use of financial incentives.

Carbon dioxide is a greenhouse gas. Carbon dioxide is generated as a byproduct of the combustion of fossil fuels and other chemical processes. The amount of carbon dioxide present in the atmosphere has steadily increased to alarming levels in recent years. Some scientist have suggested that the dramatic increase in carbon dioxide is responsible for global warming. While governments, such as the U.S.A., have not declared carbon dioxide a pollutant, they have taken steps to slow the increase of carbon dioxide present in the atmosphere.

For example, incentives exist for entities such as energy companies to reduce their emission of carbon dioxide. These incentives, in the form of financial benefits (carbon dioxide credits) are made available to both producers and consumers of energy. To take advantage of these incentives, “green-technology” systems and carbon dioxide sequestration or fixation equipment is used. To calculate carbon dioxide credits, several factors must be taken into consideration in addition to monitoring the performance of green-technology devices.

### SUMMARY OF THE INVENTION

According to one embodiment, a method for managing energy data, includes measuring an amount of power produced or consumed by an energy transformation device, measuring an amount of carbon dioxide emitted, converted or sequestered by the energy transformation device, creating a dataset of the power produced or consumed and the amount of carbon dioxide emitted, converted or sequestered and transmitting the dataset and characteristic data to a central energy data management system.

According to another embodiment, a method for managing energy data, includes receiving energy measurements and characteristic data from an energy transformation device, obtaining carbon dioxide credit information and comparing the received energy measurements and the characteristic data with the received carbon dioxide credit information to obtain a carbon dioxide credit for the energy transformation device.

According to yet another embodiment, a system for managing energy data, includes an energy transformation device, for generating or consuming energy, a database for storing carbon dioxide credit information and a central energy data management system, operably connected to the energy transformation device and the database, for comparing energy measurements and characteristic data received from the energy transformation device with carbon dioxide credit information received from the database to obtain a carbon dioxide credit for the energy transformation device.

It is to be understood that both the foregoing general description and the following detailed description are exemplary and explanatory only, and are not restrictive of the invention as claimed.

### BRIEF DESCRIPTION OF THE DRAWINGS

Features, aspects and advantages of the present invention will become apparent from the following description, appended claims, and the accompanying exemplary embodiments shown in the drawings, which are briefly described below.

FIG. 1 is a block diagram of an energy data management system according to one embodiment.

FIG. 2 is a flowchart illustrating a method for managing energy data according to one embodiment.

FIG. 3 is a flowchart illustrating a method for managing energy data according to one embodiment.

### DETAILED DESCRIPTION OF THE PREFERRED EMBODIMENTS

Embodiments of the present invention will be described below with reference to the accompanying drawings. It should be understood that the following description is intended to describe exemplary embodiments of the invention, and not to limit the invention.

Embodiments within the scope of the present invention include program products, comprising computer-readable media for carrying or having computer-executable instructions or data structures stored thereon. Such computer-readable media can be any available media that can be accessed by a general purpose or special purpose computer. By way of example, such computer-readable media can comprise RAM, ROM, EPROM, EEPROM, CD-ROM or other optical disk storage, magnetic disk storage or other magnetic storage devices, or any other medium which can be used to carry or store desired program code in the form of computer-executable instructions or data structures and which can be accessed by a general purpose or special purpose computer. When information is transferred or provided over a network or another communications connection (either hardwired, wireless, or a combination of hardwired or wireless) to a computer, the computer properly views the connection as a computer-readable medium. Thus, any such connection is properly termed a computer-readable medium. Combinations of the above are also to be included within the scope of computer-readable media. Computer-executable instructions comprise, for example, instructions and data which cause a general purpose computer, special purpose computer, or special purpose processing device to perform a certain function or group of functions.

The invention is described in the general context of method steps, which may be implemented in one embodiment by a program product including computer-executable instructions, such as program code, executed by computers in networked environments. Generally, program modules include routines, programs, objects, components, data structures, etc. that perform particular tasks or implement particular abstract data types. Computer-executable instructions, associated data structures, and program modules represent examples of program code for executing steps of the methods disclosed herein. The particular sequence of such executable instructions or associated data structures represents examples of corresponding acts for implementing the functions described in such steps.

The present invention in some embodiments, may be operated in a networked environment using logical connections to one or more remote computers having processors. Logical connections may include a local area network (LAN) and a wide area network (WAN) that are presented here by way of example and not limitation. Such networking environments are commonplace in office-wide or enterprise-wide computer networks, intranets and the Internet. Those skilled in the art will appreciate that such network computing environments will typically encompass many types of computer system configurations, including personal computers, hand-held devices, multi-processor systems, microprocessor-based or programmable consumer electronics, network PCs, minicomputers, mainframe computers, and the like. The invention may also be practiced in distributed computing environments where tasks are performed by local and remote processing devices that are linked (either by hardwired links, wireless links, or by a combination of hardwired or wireless links) through a communications network. In a distributed computing environment, program modules may be located in both local and remote memory storage devices.

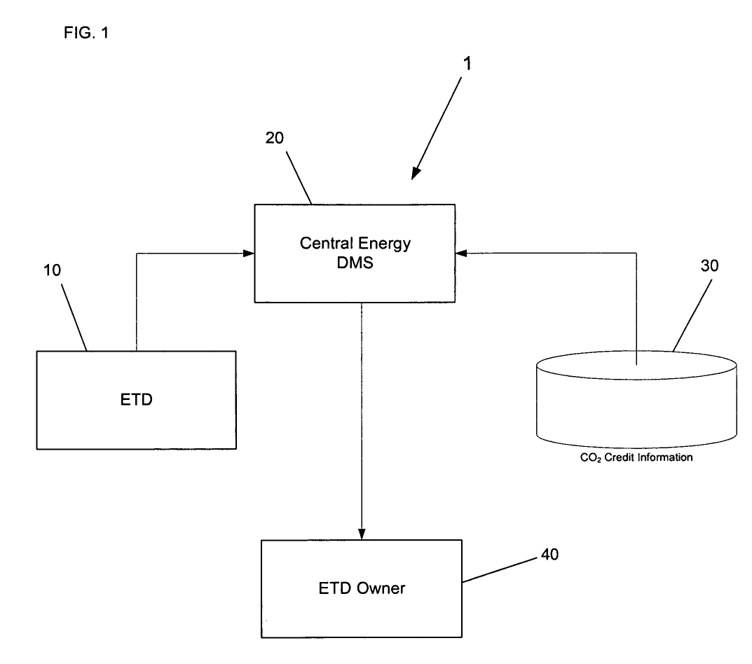

FIG. 1 is a block diagram of an energy management system 1, according to one embodiment. An energy transformation device 10 is a device that is capable of generating power and/or can consume power. For example, the energy transformation device 10 may be an electrical generator, a distributed generator (fuel cell system, wind turbine, solar energy generator), furnace scrubber, stand-alone carbon dioxide sequestration machine, bio-organic carbon dioxide fixator (algae pond) a nuclear reactor, chemical reactor or any other device capable of energy transformation. For example, device 10 is a solid oxide fuel cell power generation system. In addition to energy transformation, the energy transformation device 10 emits, converts (such as chemically converts) and/or sequesters carbon dioxide. The energy transformation device 10 is configured to measure its carbon dioxide emission, conversion and sequestration data.

A central energy data management system (DMS) 20 is operably connected to the energy transformation device 10. The energy DMS 20 is a general purpose computing device in the form of a conventional computer or sever, including a processing unit, a system memory, and a system bus that couples various system components including the system memory to the processing unit. The system memory may include read only memory (ROM) and random access memory (RAM). The computer may also include a magnetic hard disk drive for reading from and writing to a magnetic hard disk, a magnetic disk drive for reading from or writing to a removable magnetic disk, and an optical disk drive for reading from or writing to removable optical disk such as a CD-ROM or other optical media. The drives and their associated computer-readable media provide nonvolatile storage of computer-executable instructions, data structures, program modules and other data for the central energy DMS 20.

The central energy DMS 20 is also operably connected to a database 30 containing carbon dioxide credit information. Carbon dioxide credit information is information about and related to the carbon dioxide credit market, fuel cost and availability and grid power cost and availability and the like. The database 30 is a general purpose database and can be hosted on a general purpose computing device in the form of a conventional computer or sever.

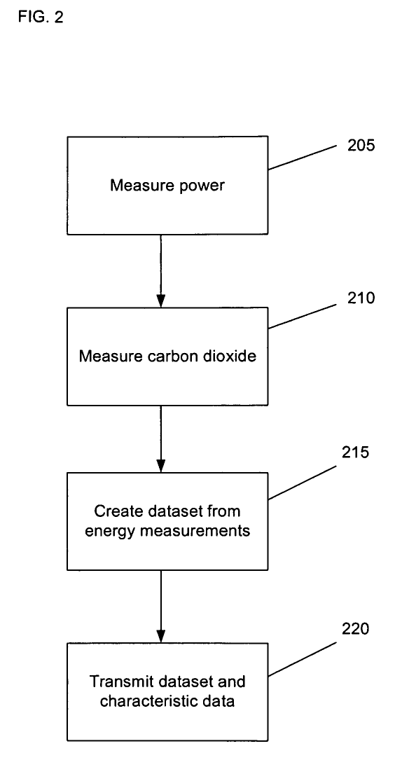

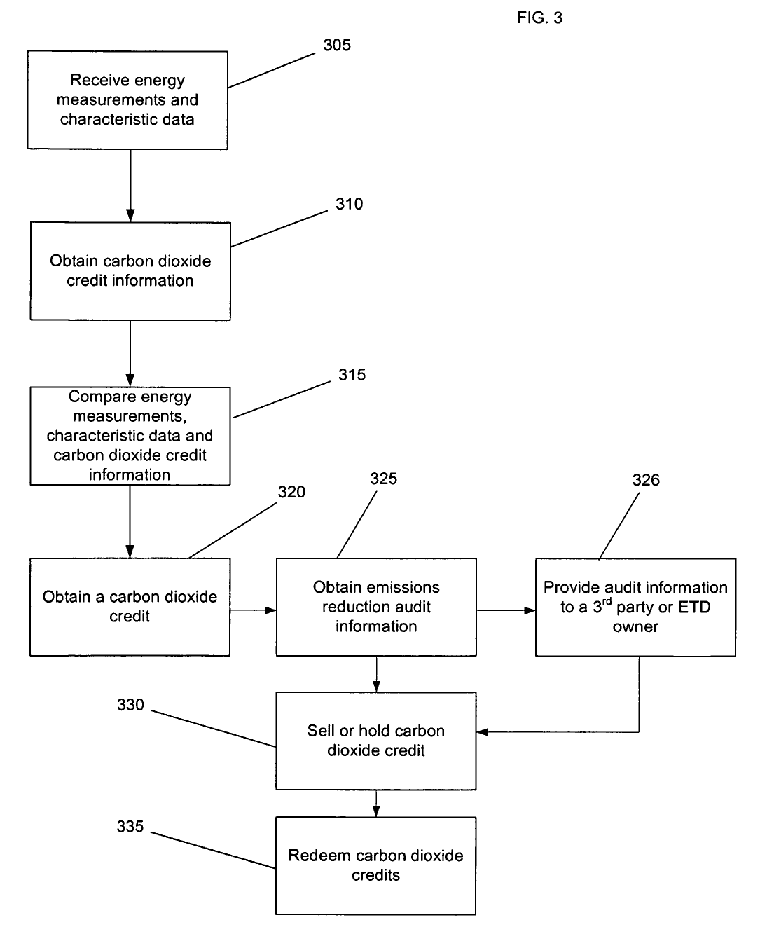

Finally, FIG. 1 shows a box 40 which represents the owner 40 of the energy transformation device 10. For example, the owner 40 can be a residential customer or an industrial/commercial customer. As depicted in FIG. 1, the owner 40 receives information from the central energy DMS 20 concerning the energy transformation device 10. Preferably, this information is received by the owner 40 with some sort of computing device, such as via the Internet through a wired or wireless connection. The functionality of the above-described energy management system 1 will now be described below with reference to FIGS. 2-3.

As shown in FIG. 2, the method and system measures the power, produced or consumed (Step 205) by device 10. Next the amount of carbon dioxide emitted, sequestered or converted by the energy transformation device 10 is measured (Step 210) over a period of time. The measurements can be taken in numerous ways. For example, if the energy transformation device 10 is a power generator, the measurement data can be collected indirectly using a ratio of the measurement of input fuel flow and output power generation. In addition, the fuel type, fuel flow and power meter of the energy transformation device 10 is used to calculate the carbon dioxide emitted based on efficiency. In the alternative, the carbon dioxide emissions can be measured per power directly, using an exhaust sampling and readings from the power meter of the energy transformation device 10. In addition, the factory measurements of carbon dioxide per power for the energy transformation device 10 can be used. Ways to measure the amount of carbon dioxide include but are not limited to measuring the carbon dioxide mass sequestered, measuring the carbon dioxide volume sequestered or counting the number of pressurized carbon dioxide gas cylinders filled. A fuel cell system which sequesters CO₂ is described in U.S. patent application Ser. No. 11/404,760, incorporated by reference herein in its entirety.

For a prescribed time period, the collected measurement information for the energy transformation device 10 is recorded as a dataset (step 215). The dataset also includes characteristic data. Characteristic data is data related to the energy transformation device 10. For example, characteristic data can include the location (e.g., address) of the energy transformation device 10, the name of the customer who owns, leases, rents or is responsible for the energy transformation device 10, load profile data, fuel consumption data, credit owner information and time-stamp data. According to one embodiment, the characteristic data can be in the form of metadata.

The system and method transmits the dataset with the characteristic data to the central energy DMS 20 (Step 220). The dataset may be transmitted via the Internet, wirelessly or via electronic or fiber optic cables. The data set may be recorded in a computer or processor associated with embedded in device 10.

The format in which the dataset is transmitted can vary in several ways. According to one embodiment, the dataset can be constantly streamed to the central energy DMS 20. According to another embodiment, the dataset can be accumulated and stored in the energy transformation device 10 (or in an associated computer) for a specific time period (e.g., one day) and then transmitted at the end of that specific time interval. In addition to receiving the data set and characteristic data (Step 305), as shown in FIG. 3, the central energy DMS 20 obtains (receive from a remoter source, e.g., the Internet or lookup from stored data) carbon dioxide credit information from the database 30 (Step 310). This may include CO2 credit market values, fuel costs and availabilities and grid power costs and availabilities, etc. The time period related to the carbon dioxide credit information is the same as the time period related to the dataset and characteristic data transmitted to the central DMS 20 by the energy transformation device 10.

The central energy DMS 20 compares the dataset and characteristic data to the obtained carbon dioxide credit information (Step 315) to calculate carbon dioxide credits (Step 320). Similarly, the central energy DMS 20 obtains an emission reduction calculation by comparing the carbon dioxide emitted or sequestered with infrastructure emissions and sequestration data.

If the energy transformation device 10 is operated at a residential facility (e.g., house, apartment, building, etc.) the following steps are executed. The system and method creates an audit trail of emissions reduction (325) with, for example, (1) the carbon dioxide credit, (2) the dataset obtained from the energy measurements, and (3) the carbon dioxide credit information obtained from the database 30. Then, the carbon dioxide credit can be sold or held for filing of incentive paperwork with municipalities (Step 330). Next, the system and method facilitate the redemption of the carbon dioxide credits (Step 335). This may include redemption by mail, via the Internet, direct credit to an account or discounted purchase through an energy provider who has purchased carbon dioxide credits.

In contrast, if the energy transformation device 10 is operated at a industrial/commercial facility (e.g., business, manufacturing plant, etc.) the following steps are executed. The system and method creates an audit trail of emissions reduction (325) with, for example, (1) the carbon dioxide credit, (2) the dataset obtained from the energy measurements, and (3) the carbon dioxide credit information obtained from the database 30. The audit information is filed with municipalities on behalf of the industrial customer (Step 326). In the alternative, the audit information can be transmitted back to the energy transformation device 10 for storage (Step 326). Paperwork is processed for claiming financial incentives or market sales of the carbon dioxide credits if appropriate. According to one embodiment, the central energy DMS 20, using standard protocols, can interface with the industrial customer's ERP and/or accounting systems to transfer the audit information. Then, the carbon dioxide credit can be sold or held for filing of incentive paperwork with municipalities (Step 330 or 335). This creates the ability to generate derivative financial instruments based on the credits (options, swaps, forwards, collars, etc.). For example, a collar is an investment strategy that uses options to limit the possible range of positive or negative returns on an investment in an underlying asset to a specific range.

The presently disclosed method and system has several advantages. For example, the disclosed system and method reduces the cost of collecting carbon dioxide emissions data. One way in which the collection of data is streamlined is by tagging carbon dioxide emission, conversion and/or sequestration with metadata related to a energy transformation device in order to properly identify devices and entities that have earned carbon dioxide credit. The disclosed method and system also facilitates the selling of carbon dioxide credits.

The foregoing description of a preferred embodiment of the invention has been presented for purposes of illustration and description. It is not intended to be exhaustive or to limit the invention to the precise form disclosed, and modifications and variations are possible in light of the above teaching or may be acquired from practice of the invention. The embodiment was chosen and described in order to explain the principles of the invention and as a practical application to enable one skilled in the art to utilize the invention in various embodiments and with various modification are suited to the particular use contemplated. It is intended that the scope of the invention be defined by the claims appended hereto and their equivalents.

What is claimed is:

1. A method for managing energy data, comprising:
measuring an amount of power produced or consumed by an energy transformation device;
measuring an amount of carbon dioxide emitted, converted or sequestered by the energy transformation device;
creating a dataset of the power produced or consumed and the amount of carbon dioxide emitted, converted or sequestered; and
transmitting the dataset and characteristic data to a central energy data management system.

2. A method as claimed in claim 1, wherein the characteristic data includes temporal data, location data, a site address, a customer name, load profile data, fuel consumption data, or emission credit owner data unique to the energy transformation device.

3. A method as claimed in claim 1, wherein the amount of power produced and the amount of carbon dioxide emitted by the energy transformation device is obtained using a ratio measurement of input fuel flow to output power generation by the energy transformation device.

4. A method for managing energy data, comprising:
receiving energy measurements and characteristic data from an energy transformation device;
obtaining carbon dioxide credit information; and
comparing the received energy measurements and the characteristic data with the received carbon dioxide credit information to obtain a carbon dioxide credit for the energy transformation device.

5. A method as claimed in claim 4, wherein the characteristic data includes temporal data, location data, a site address, a customer name, load profile data, fuel consumption data, or emission credit owner data unique to the energy transformation device.

6. A method as claimed in claim 4, wherein the energy measurements include a power production measurement, a power consumption measurement, a carbon dioxide emission measurement, or a carbon dioxide sequestration measurement.

7. A method as claimed in claim 6, wherein the carbon dioxide credit is based upon an emissions reduction calculation which is obtained by comparing the carbon dioxide emission measurement with the carbon dioxide credit information.

8. A method as claimed in claim 6, wherein the carbon dioxide credit is based upon an emissions reduction calculation which is obtained by comparing the carbon dioxide sequestration measurement with the carbon dioxide credit information.

9. A method as claimed in claim 4, further comprising:
recording the carbon dioxide credit, the energy measurements, a metadata of the characteristic data and the carbon dioxide credit information to obtain emissions reduction audit information;
selling the carbon dioxide credits; and
providing payment for the carbon dioxide credits to an owner of the energy transformation device.

10. A method as claimed in claim 4, further comprising:
recording the carbon dioxide credit, the energy measurements, a metadata of the characteristic data and the carbon dioxide credit information to obtain emissions reduction audit information;
providing the emissions reduction audit information to a third party;
selling the carbon dioxide credits; and
providing payment for the carbon dioxide credits to an owner of the energy transformation device.

11. A method for managing energy data of an energy transformation device, comprising:
measuring an amount of power produced or consumed by an energy transformation device;
measuring an amount of carbon dioxide emitted, converted or sequestered by the energy transformation device;
creating a dataset of the power produced or consumed and the amount of carbon dioxide emitted or sequestered;
transmitting the dataset and characteristic data to a central energy data management system;
receiving energy measurements and characteristic data from an energy transformation device;
receiving carbon dioxide credit information; and
comparing the received energy measurements and the characteristic data with the received carbon dioxide credit information to obtain a carbon dioxide credit for the energy transformation device.

12. A method as claimed in claim 11, wherein the characteristic data includes temporal data, location data, a site address, a customer name, load profile data, fuel consumption data, or emission credit owner data unique to the energy transformation device.

13. A method as claimed in claim 11, further comprising:
recording the carbon dioxide credit, the energy measurements, a metadata of the characteristic data and the carbon dioxide credit information to obtain emissions reduction audit information;
selling the carbon dioxide credits; and
providing payment for the carbon dioxide credits to an owner of the energy transformation device.

14. A method as claimed in claim 11, further comprising:
recording the carbon dioxide credit, the energy measurements, a metadata of the characteristic data and the carbon dioxide credit information to obtain emissions reduction audit information;
providing the emissions reduction audit information to a third party;
selling the carbon dioxide credits; and
providing payment for the carbon dioxide credits to an owner of the energy transformation device.

15. A system for managing energy data, comprising:
an energy transformation device, for generating or consuming energy;
a database for storing carbon dioxide credit information; and
a central energy data management system, operably connected to the energy transformation device and the database, for comparing energy measurements and characteristic data received from the energy transformation device with carbon dioxide credit information received from the database to obtain a carbon dioxide credit for the energy transformation device.

16. A system as claimed in claim 15, wherein in the energy transformation device further comprises a processor for executing a computer program, embodied on a computer readable medium, wherein the computer program comprises computer code for:
measuring an amount of power produced or consumed by the energy transformation device;
measuring an amount of carbon dioxide emitted, converted or sequestered by the energy transformation device;
creating a dataset of the power produced or consumed and the amount of carbon dioxide emitted, converted or sequestered; and
transmitting the dataset and characteristic data to the central energy data management system.

17. A system as claimed in claim 15, wherein in the central energy data management system further comprises a processor for executing a computer program, embodied on a computer readable medium, wherein the computer program comprises computer code for:
receiving energy measurements and characteristic data from an energy transformation device;
obtaining carbon dioxide credit information; and
comparing the received energy measurements and the characteristic data with the received carbon dioxide credit information to obtain a carbon dioxide credit for the energy transformation device.

18. The method of claim 1, wherein the method is implemented on a computer.

19. The method of claim 4, wherein the method is implemented on a computer.

20. The method of claim 11, wherein the method is implemented on a computer.
